(19) United States
(12) Patent Application Publication
(10) Pub. No.: US 2017/0162809 A1
(43) Pub. Date: Jun. 8, 2017

(54) PEROVSKITE THIN-FILM PHOTOVOLTAIC CELL AND PREPARATION METHOD THEREOF

(71) Applicant: WUHAN UNIVERSITY, Wuhan (CN)

(72) Inventors: Guojia FANG, Wuhan (CN); Weijun KE, Wuhan (CN); Qin LIU, Wuhan (CN); Hong TAO, Wuhan (CN); Hongwei LEI, Wuhan (CN); Jing WANG, Wuhan (CN)

(21) Appl. No.: 15/436,891

(22) Filed: Feb. 20, 2017

Related U.S. Application Data
(63) Continuation-in-part of application No. PCT/CN2015/074753, filed on Mar. 20, 2015.

(30) Foreign Application Priority Data
Aug. 19, 2014 (CN) 201410407708.9

(51) Int. Cl. H01L 51/44; H01L 51/42

(52) U.S. Cl. CPC H01L 51/442; H01L 51/4226

(57) ABSTRACT

A perovskite thin-film photovoltaic cell, including: a transparent conductive substrate, an electron transport layer, a perovskite absorption layer, a hole transport layer, and a metal electrode in that order. The electron transport layer is a tin dioxide thin-film. The invention also provides a method for preparing the perovskite thin-film photovoltaic cell. The method includes: (1) cleaning the transparent conductive substrate and then drying the transparent conductive substrate using nitrogen gas; (2) coating a SnO₂ electron transport layer on the transparent conductive substrate; (3) coating a CH₃NH₃PbI₃₋ₓClₓ or CH₃NH₃PbI₃ absorber on the electron transport layer; and (4) spin-coating a solution including hole transport material on the perovskite absorber layer and then evaporating the metal electrode.

### CROSS-REFERENCE TO RELATED APPLICATIONS

This application is a continuation in part of International Patent Application No. PCT/CN2015/074753 with an international filing date of Mar. 20, 2015, designating the United States, now pending, and further claims priority benefits to Chinese Patent Application No. 201410407708.9 filed Aug. 19, 2014. The contents of all of the aforementioned applications, including any intervening amendments thereto, are incorporated herein by reference. Inquiries from the public to applicants or assignees concerning this document or the related applications should be directed to: Matthias Scholl P.C., Attn.: Dr. Matthias Scholl Esq., 245 First Street, 18th Floor, Cambridge, Mass. 02142.

### BACKGROUND OF THE INVENTION

Field of the Invention

The invention provides a perovskite thin-film photovoltaic cell and preparation method thereof.

Description of the Related Art

Solar energy is practically inexhaustible, and photovoltaic cells can convert solar energy into electricity directly. Solar cells have developed from silicon solar cells to the third generation of dye-sensitized solar cells, organic solar cells, and CuInGaSe solar cells. However, the production cost of solar cells is high and the long term stability of solar cells leaves much to be desired.

Perovskite solar cells have attracted much attention recently due to their excellent photovoltaic properties. Efficient perovskite solar cells usually use high temperature sintered TiO₂ thin films as electron transporting layers (ETLs), which transport electrons and block holes and therefore reduce their recombination. The high quality TiO₂ ETLs are usually sintered at 400-500° C. and the perovskite solar cells using the low temperature processed TiO₂ ETLs have much lower performance Therefore, it is critical to find an alternative, low-temperature processed ETL.

It is reported that perovskite solar cells using low-temperature solution-processed ZnO ETLs achieve high efficiencies. However, ZnO is not stable and is easily dissolved in both acid and base solution, which will seriously hinder industrial applicability. Even though the efficiency of perovskite solar cells may be very high, the fabrication process and the cost and the stability of the cells are still unsatisfactory.

### SUMMARY OF THE INVENTION

In view of the above-described problems, it is one objective of the invention to provide a method of producing efficient perovskite solar cells using a novel metal oxide as ETL, which is low-cost and stable.

To achieve the above objective, in accordance with one embodiment of the invention, there is provided a perovskite thin-film photovoltaic cell, which comprises a transparent conductive substrate, an electron transport layer, a perovskite absorption layer, a hole transport layer, and a metal electrode in that order. The electron transport layer is a tin dioxide thin-film.

In a class of this embodiment, the transparent conductive substrate is fluorine-doped tin oxide (FTO) or indium tin oxide (ITO).

In a class of this embodiment, the perovskite absorption layer is CH₃NH₃PbI₃₋ₓClₓ or CH₃NH₃PbI₃ thin-film, and x is an integer from 0 to 3.

In a class of this embodiment, the hole transport layer is a mixed solution comprising 68 mM of
2,2′,7,7′-tetrakis[N,N-di(4-methoxyphenyl)amino]-9,9′-spirobifluorene, 26 mM of Li-FTSI, and 55 mM of 4-tert butyl pyridine, and a solvent of the mixed solution is a mixture of chlorobenzene and acetonitrile having a volume ratio of chlorobenzene: acetonitrile being 10:1.

In a class of this embodiment, the metal electrode is a gold electrode.

The invention also provides a method of preparing the perovskite thin-film photovoltaic cell, the method comprising:
(1) cleaning the transparent conductive substrate by a standard semiconductor technology and then drying the transparent conductive substrate using nitrogen gas;
(2) coating a SnO₂ electron transport layer on the transparent conductive substrate;
(3) coating a CH₃NH₃PbI₃₋ₓClₓ or CH₃NH₃PbI₃ absorber on the electron transport layer; and
(4) spin-coating a solution comprising hole transport material on the perovskite absorber layer and then evaporating the metal electrode.

In a class of this embodiment, a preparation method of the SnO₂ electron transport layer comprises:
(1) stirring an ethanol solution comprising 0.025-0.2 mol/L SnCl₂.2H₂O for 30 min;
(2) spin-coating the ethanol solution of SnCl₂.2H₂O on the transparent conductive substrate; and
(3) annealing the electron transport layer at 180-400° C. for 30 min.

In a class of this embodiment, a preparation method of the CH₃NH₃PbI₃₋ₓClₓ absorber comprises:
(1) stirring a perovskite solution comprising CH₃NH₃I and PbCl₂ with a molar ratio of 3:1 dissolved in dimethylformamide at 60° C. for 24 h;
(2) spin-coating the perovskite solution on the electron transport layer; and
(3) annealing the perovskite absorber layer at 100° C. for 45 min

In a class of this embodiment, a preparation method of the CH₃NH₃PbI₃ absorber comprises:
(1) stirring a PbI₂ solution dissolved in dimethylformamide at 60° C. for 24 h;
(2) spin-coating the PbI₂ solution on the electron transport layer and then annealing the electron transport layer at 70° C. for 30 min;
(3) soaking the transparent conductive substrate into an isopropanol solution comprising 10 mg/L CH₃NH₃I for 5 min; and
(4) rinsing the transparent conductive substrate with isopropanol and drying the transparent conductive substrate by nitrogen and then annealing at 70° C. for 30 min.

The invention employs a simple and efficient method to produce a novel ETL material for perovskite solar cells at low temperatures, which reduces the production cost of TiO₂ ETLs and avoids the sintering at high temperatures.

Advantages of the perovskite solar cell of the invention are summarized as follows: 1. The use of low temperature processed SnO₂ thin films as ETLs for perovskite solar cells to replace the conventional high temperature sintered TiO₂ thin films, which significantly reduce the fabrication cost. 2. The SnO₂ ETLs based perovskite solar cells achieve high photoelectric conversion efficiency (14.6%), which is comparable with the ZnO ETLs based perovskite solar cells. 3. SnO₂ is a very stable material, much more stable than many metal oxides, such as TiO₂ and ZnO, and therefore will benefit the long term stability of the devices. 4. For the simple, low-cost, and good reproducibility fabrication process, it paves a way for preparing large-scale perovskite solar cells and has a good potential for the commercialization.

### BRIEF DESCRIPTION OF THE DRAWINGS

FIG. 1 shows a schematic diagram of a perovskite solar cell according to one embodiment of the invention, where 1, 2, 3, 4, and 5 represent FTO, ETL, perovskite absorber, HTL, and mental electrode, respectively;

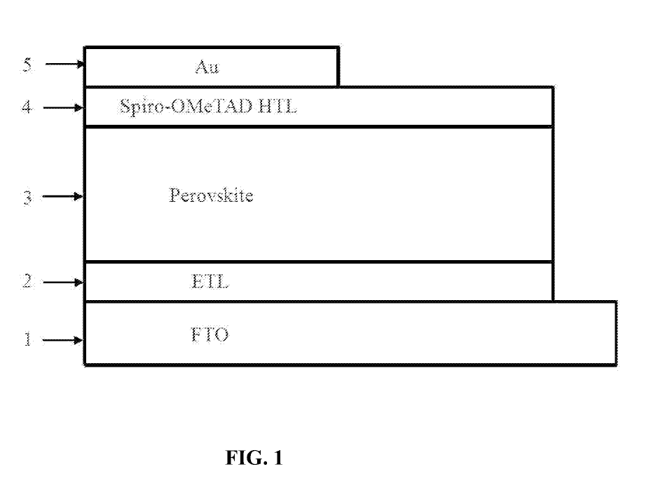

FIG. 2 shows a JV curve of a perovskite solar cell described in Example 1;

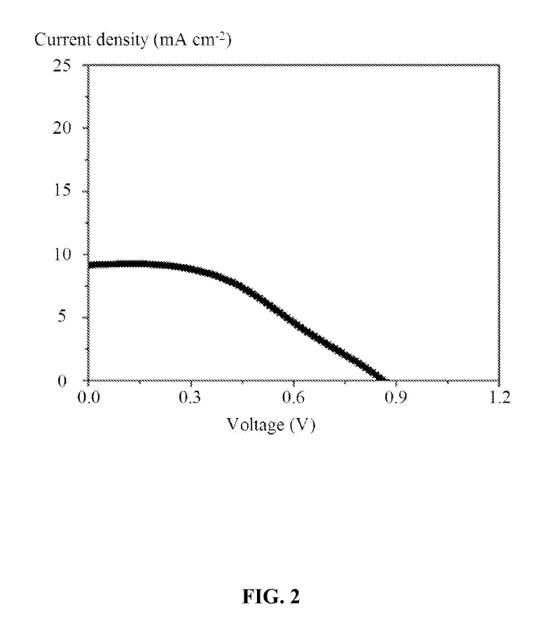

FIG. 3 shows a JV curve of a perovskite solar cell described in Example 2;

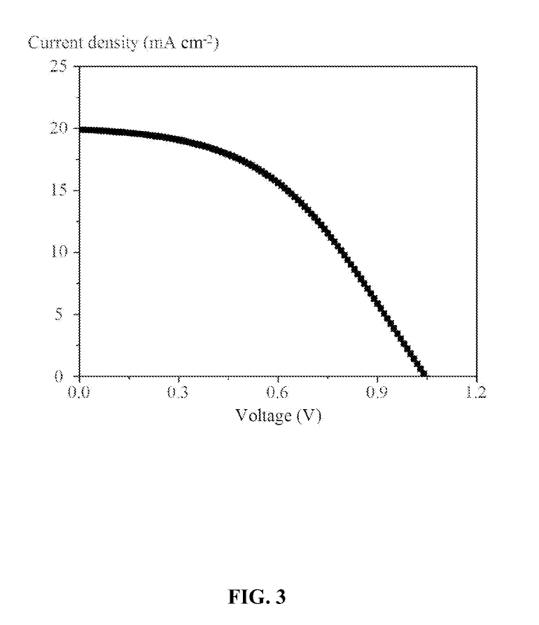

FIG. 4 shows a JV curve of a perovskite solar cell described in Example 3;

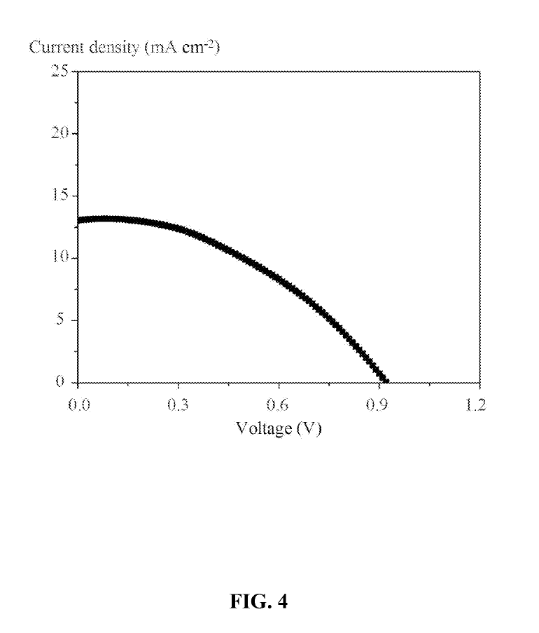

FIG. 5 shows a JV curve of a perovskite solar cell described in Example 4;

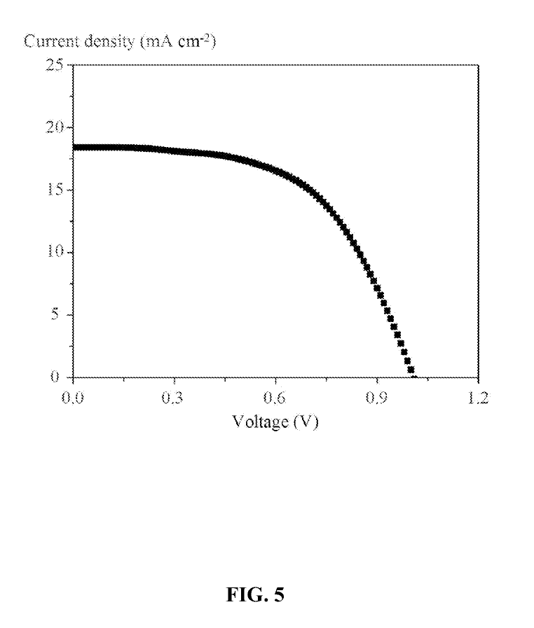

FIG. 6 shows a JV curve of a perovskite solar cell described in Example 5;

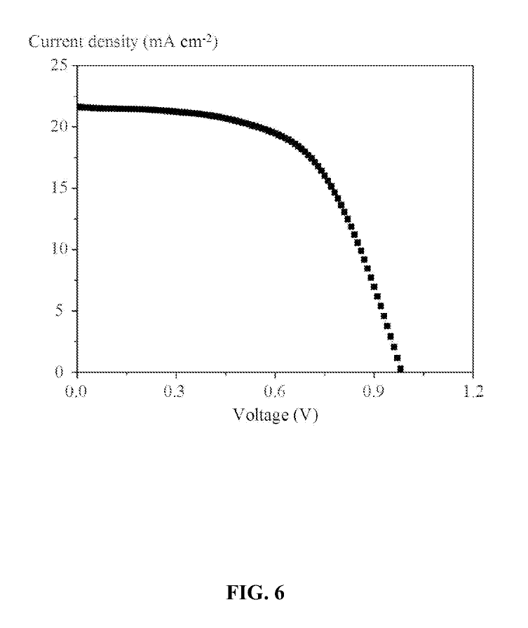

FIG. 7 shows a JV curve of a perovskite solar cell described in Example 6;

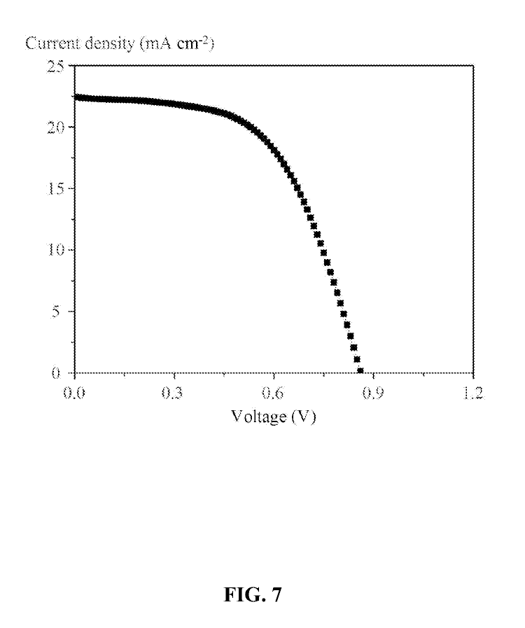

FIG. 8 shows a JV curve of a perovskite solar cell described in Example 7;

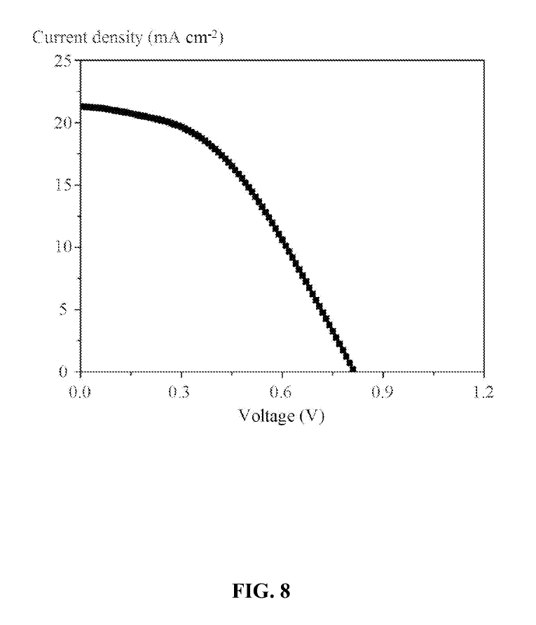

FIG. 9 shows a JV curve of a perovskite solar cell described in Example 8;

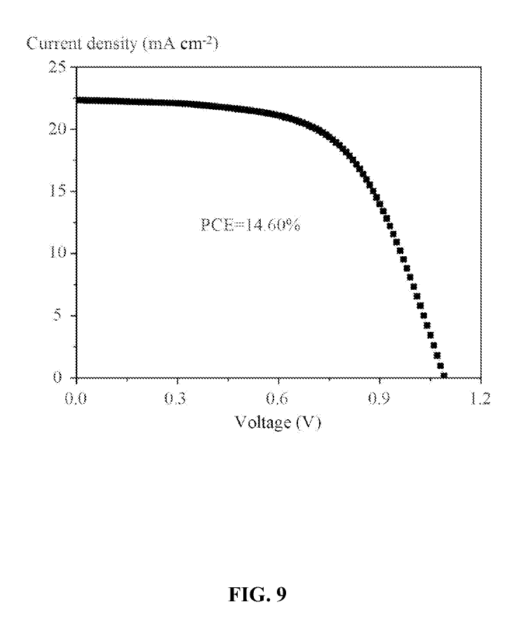

FIG. 10 shows a JV curve of a perovskite solar cell described in Example 9; and

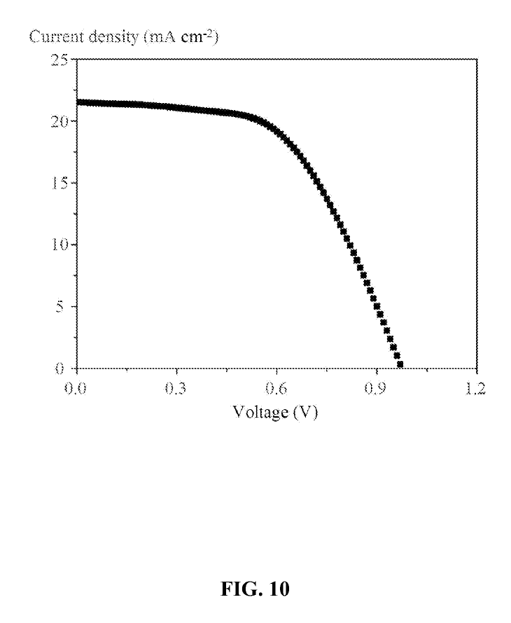

FIG. 11 shows transmission spectra of an FTO substrate and an FTO substrate coated with a compact layer in Example 10.

### DETAILED DESCRIPTION OF THE EMBODIMENTS

### EXAMPLE 1

1. The cleaning process of substrate. FTO substrate was cleaned and dried. Firstly, the FTO substrate was cut to a suitable size and cleaned by detergent and washed by deionized water. Secondly, the substrate was washed by an ultrasonic cleaner sequentially in acetone, ethanol, and deionized water. Finally, the substrate was dried by nitrogen gas.

2. The fabrication of perovskite CH₃NH₃PbI₃ absorber. Firstly, 1 mol/L PbI₂ in dimethylformamide was stirred at 60° C. for 12 h. The solution was spin-coated on an FTO substrate without ETL. Secondly, the substrate was soaked into 10 mg/mL CH₃NH₃I in isopropanol for 5 min and then soaked into clean isopropanol at room temperature. Finally, the film was dried by nitrogen gas and heated in air at 70° C. for 30 min.

3. The fabrication of HTL. The perovskite film was spin-coated with HTL using a solution composed of 68 mM of spiro-OMeTAD, 26 mM of Li-TFSI, and 55 mM of TBP dissolved in acetonitrile and chlorobenzene (V/V=1:10).

4. The fabrication of electrode. The sample coated with HTL was put into an evaporator and deposited with an Au film as the electrode.

5. The test of performance. The device with an active area of 0.09 cm² was measured under AM1.5G illumination. The perovskite solar cell achieved a power conversion efficiency (PCE) of 3.32% with an open circuit voltage (V_{oc}) of 0.87 V, a short-circuit current densities (J_{sc}) of 9.15 mA/cm², and a fill factor (FF) of 0.42.

### EXAMPLE 2

1. The cleaning process of the transparent conductive substrate is the same as Example 1.

2. The fabrication of TiO₂ ETL. To prepare the precursor solution, 0.38 mL of diethanolamine, 1.8 mL of tetrabutyl titanate, and 18 mL of ethanol were stirred at 40° C. for 2 h. To form a sol, the solution should be aged for 24 h. A compact TiO₂ film was coated by a spin coating method and then thermally annealed at 550° C. for 30 min.

3. The fabrication of perovskite CH₃NH₃PbI₃ absorber. Firstly, 1 mol/L PbI₂ in dimethylformamide was stirred at 60° C. for 12 h. The solution was spin-coated on an FTO substrate with TiO₂ ETL. Secondly, the substrate was soaked into 10 mg/mL CH₃NH₃I in isopropanol for 5 min and then soaked into clean isopropanol at room temperature. Finally, the film was dried by nitrogen gas and heated in air at 70° C. for 30 min.

4. The fabrication of HTL is the same as that in Example 1.

5. The fabrication of electrode is the same as that in Example 1.

6. The Test of performance. The device with an active area of 0.09 cm² was measured under AM1.5G illumination. The perovskite solar cell achieved a PCE of 9.43% with a V_{oc} of 1.05 V, a J_{sc} of 19.91 mA/cm², and an FF of 0.45.

### EXAMPLE 3

1. The cleaning process of the transparent conductive substrate is the same as that in Example 1.

2. The fabrication of SnO₂ ETL. 0.025 mol/L SnCl₂.2H₂O dissolved in ethanol was stirred at room temperature for 30 min. The precursor solution was spin-coated on an ITO substrate and then thermally annealed at 400° C. for 30 min.

3. The fabrication of perovskite CH₃NH₃PbI₃ absorber. Firstly, 1 mol/L PbI₂ in dimethylformamide was stirred at 60° C. for 12 h. The solution was spin-coated on an FTO substrate with SnO₂ ETL. Secondly, the substrate was soaked into 10 mg/mL CH₃NH₃I in isopropanol for 5 min and then soaked into clean isopropanol at room temperature. Finally, the film was dried by nitrogen gas and heated in air at 70° C. for 30 min.

4. The fabrication of HTL is the same as that in Example 1.

5. The fabrication of electrode is the same as that in Example 1.

6. The Test of performance. The device with an active area of 0.09 cm² was measured under AM1.5G illumination. The perovskite solar cell achieved a PCE of 5.03% with a V_{oc} of 0.93 V, a J_{sc} of 13.06 mA/cm², and an FF of 0.42.

### EXAMPLE 4

1. The cleaning process of the substrate is the same as that in Example 1.

2. The fabrication of SnO₂ ETL. 0.05 mol/L SnCl₂.2H₂O dissolved in ethanol was stirred at room temperature for 30 min The precursor solution was spin-coated on an FTO substrate and then thermally annealed at 400° C. for 30 min.

3. The fabrication of perovskite CH₃NH₃PbI₃ absorber. Same as Example 3.

The fabrication of HTL is the same as that in Example 1.

5. The fabrication of electrode is the same as that in Example 1.

6. The Test of performance. The device with an active area of 0.09 cm² was measured under AM1.5G illumination. The perovskite solar cell achieved a PCE of 10.52% with a V_{oc} of 1.01 V, a J_{sc} of 18.42 mA/cm², and an FF of 0.57.

### EXAMPLE 5

1. The cleaning process of the transparent conductive substrate is the same as that in Example 1.

2. The fabrication of SnO₂ ETL. 0.075 mol/L SnCl₂.2H₂O dissolved in ethanol was stirred at room temperature for 30 min. The precursor solution was spin-coated on an FTO substrate and then thermally annealed at 400° C. for 30 min.

3. The fabrication of perovskite CH₃NH₃PbI₃ absorber. Same as Example 3.

4. The fabrication of HTL is the same as that in Example 1.

5. The fabrication of electrode is the same as that in Example 1.

6. The Test of performance. The device with an active area of 0.09 cm² was measured under AM1.5G illumination. The perovskite solar cell achieved a PCE of 12.41% with a V_{oc} of 0.99 V, a J_{sc} of 21.64 mA/cm², and an FF of 0.58.

### EXAMPLE 6

1. The cleaning process of the transparent conductive substrate is the same as that in Example 1.

2. The fabrication of SnO₂ ETL. 0.1 mol/L SnCl₂.2H₂O dissolved in ethanol was stirred at room temperature for 30 min The precursor solution was spin-coated on an FTO substrate and then thermally annealed at 400° C. for 30 min.

3. The fabrication of perovskite CH₃NH₃PbI₃ absorber. Same as Example 3.

4. The fabrication of HTL is the same as that in Example 1.

5. The fabrication of electrode is the same as that in Example 1.

6. The test of performance. The device with an active area of 0.09 cm² was measured under AM1.5G illumination. The perovskite solar cell achieved a PCE of 10.90% with a V_{oc} of 0.87 V, a J_{sc} of 22.44 mA/cm², and an FF of 0.56.

### EXAMPLE 7

1. The cleaning process of the transparent conductive substrate is the same as that in Example 1.

2. The fabrication of SnO₂ ETL. 0.2 mol/L SnCl₂.2H₂O dissolved in ethanol was stirred at room temperature for 30 min The precursor solution was spin-coated on an FTO substrate and then thermally annealed at 400° C. for 30 min.

3. The fabrication of perovskite CH₃NH₃PbI₃ absorber. Same as Example 3.

4. The fabrication of HTL is the same as that in Example 1.

5. The fabrication of electrode is the same as that in Example 1.

6. The test of performance. The device with an active area of 0.09 cm² was measured under AM1.5G illumination. The perovskite solar cell achieved a PCE of 7.46% with a V_{oc} of 0.82 V, a J_{sc} of 21.30 mA/cm², and an FF of 0.43.

### EXAMPLE 8

1. The cleaning process of the transparent conductive substrate is the same as that in Example 1.

2. The fabrication of SnO₂ ETL. 0.075 mol/L SnCl₂.2H₂O dissolved in ethanol was stirred at room temperature for 30 min. The precursor solution was spin-coated on an FTO substrate and then thermally annealed at 180° C. for 30 min.

3. The fabrication of perovskite CH₃NH₃PbI₃ absorber. Same as Example 3.

4. The fabrication of HTL is the same as that in Example 1.

5. The fabrication of electrode is the same as that in Example 1.

6. The test of performance. The device with an active area of 0.09 cm² was measured under AM1.5G illumination. The perovskite solar cell achieved a PCE of 14.60% with a V_{oc} of 1.10 V, a J_{sc} of 22.37 mA/cm², and an FF of 0.59.

### EXAMPLE 9

1. The cleaning process of the transparent conductive substrate is the same as that in Example 1.

2. The fabrication of SnO₂ ETL is the same as that in Example 5.

3. The fabrication of perovskite CH₃NH₃PbI₃Clₓ absorber. A precursor solution of CH₃NH₃PbI₃ₓClₓ composed of CH₃NH₃I and PbCl₂ with a molar ratio of 3:1 in anhydrous dimethylformamide was stirred at room temperature for 24 h. The solution was spin-coated on an FTO substrate with SnO₂ ETL and then annealed at 100° C. for 45 min.

4. The fabrication of HTL is the same as that in Example 1.

5. The fabrication of electrode is the same as that in Example 1.

6. The test of performance. The device with an active area of 0.09 cm² was measured under AM1.5G illumination. The perovskite solar cell achieved a PCE of 11.61% with a V_{oc} of 0.98 V, a J_{sc} of 21.53 mA/cm², and an FF of 0.55.

### EXAMPLE 10

1. The cleaning process of substrates is the same as in Example 1.

2. The fabrication of TiO₂ ETL is the same as in Example 2. About 50 nm thick TiO₂ film was coated on FTO substrate.

3. The fabrication of SnO₂ ETL is the same as in Example 8. About 50 nm thick SnO₂ film was coated on FTO substrate.

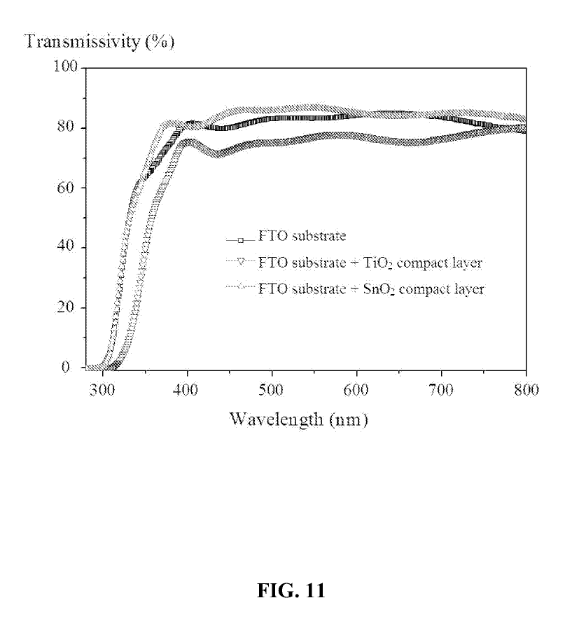

4. The test of performance. Transmission spectra of FTO substrate, SnO₂ coated FTO and TiO₂ coated FTO were characterized by an ultraviolet-visible (UV-vis) spectrophotometer. The obtained transmission spectra are illustrated in FIG. 11. These results illustrate that the obtained SnO₂ film has wider optical band gap than that of the TiO₂ film, and the obtained SnO₂ ETL has good optical antireflection property.

This invention relates to a method of preparing perovskite solar cells based on the low temperature processed SnO₂ ETLs have achieved high efficiencies, which are much better than that of the perovskite solar cells based on the high temperature sintered TiO₂ ETLs. The high performance has been obtained for the perovskite solar cells based on either CH₃NH₃PbI₃ or CH₃NH₃PbI₃ₓClₓ absorber with the SnO₂ ETLs. This simple low temperature process is compatible with the roll to roll manufacturing of low-cost perovskite solar cells on flexible substrates.

The invention claimed is:

1. A perovskite thin-film photovoltaic cell, comprising: a transparent conductive substrate, an electron transport layer, a perovskite absorption layer, a hole transport layer, and a metal electrode, arranged in that order one next to the other, wherein the electron transport layer is a tin dioxide thin-film.

2. The solar cell of claim 1, wherein the transparent conductive substrate is fluorine-doped tin oxide (FTO) or indium tin oxide (ITO).

3. The solar cell of claim 1, wherein the perovskite absorption layer is CH₃NH₃PbI₃₋ₓClₓ or CH₃NH₃PbI₃ thin-film, and x is an integer from 0 to 3.

4. The solar cell of claim 2, wherein the perovskite absorption layer is CH₃NH₃PbI₃₋ₓClₓ or CH₃NH₃PbI₃ thin-film, and x is an integer from 0 to 3.

5. The solar cell of claim 1, wherein the hole transport layer is a mixed solution comprising 68 mM of
2,2′,7,7′-tetrakis[N,N-di(4-methoxyphenyeamino]-9,9′-spirobifluorene, 26 mM of Li-FTSI, and 55 mM of 4-tert butyl pyridine, and a solvent of the mixed solution is a mixture of chlorobenzene and acetonitrile having a volume ratio of chlorobenzene: acetonitrile of 10:1.

6. The solar cell of claim 2, wherein the hole transport layer is a mixed solution comprising 68 mM of
2,2′,7,7′-tetrakis[N,N-di(4-methoxyphenyeamino]-9,9′-spirobifluorene, 26 mM of Li-FTSI, and 55 mM of 4-tert butyl pyridine, and a solvent of the mixed solution is a mixture of chlorobenzene and acetonitrile having a volume ratio of chlorobenzene: acetonitrile of 10:1.

7. The solar cell of claim 1, wherein the metal electrode is a gold electrode.

8. The solar cell of claim 2, wherein the metal electrode is a gold electrode.

9. A method of preparing the perovskite thin-film photovoltaic cell of claim 1, the method comprising:
(1) cleaning the transparent conductive substrate and then drying the transparent conductive substrate using nitrogen gas;
(2) coating a SnO₂ electron transport layer on the transparent conductive substrate;
(3) coating a CH₃NH₃PbI₃₋ₓClₓ or CH₃NH₃PbI₃ absorber on the electron transport layer; and
(4) spin-coating a solution comprising hole transport material on the perovskite absorber layer and then evaporating the metal electrode.

10. The method of claim 9, wherein a preparation method of the SnO₂ electron transport layer comprises:
(1) stirring an ethanol solution comprising 0.025-0.2 mol/L SnCl₂.2H₂O for 30 min;
(2) spin-coating the ethanol solution of SnCl₂.2H₂O on the transparent conductive substrate; and
(3) annealing the electron transport layer at 180-400° C. for 30 min.

11. The method of claim 9, wherein a preparation method of the CH₃NH₃PbI₃₋ₓClₓ absorber comprises:
(1) stirring a perovskite solution comprising CH₃NH₃I and PbCl₂ with a molar ratio of 3:1 dissolved in dimethylformamide at 60° C. for 24 h;
(2) spin-coating the perovskite solution on the electron transport layer; and
(3) annealing the perovskite absorber layer at 100° C. for 45 min

12. The method of claim 9, wherein a preparation method of the CH₃NH₃PbI₃ absorber comprises:
(1) stirring a PbI₂ solution dissolved in dimethylformamide at 60° C. for 24 h;
(2) spin-coating the PbI₂ solution on the electron transport layer and then annealing the electron transport layer at 70° C. for 30 min;
(3) soaking the transparent conductive substrate into an isopropanol solution comprising 10 mg/L CH₃NH₃I for 5 min; and
(4) rinsing the transparent conductive substrate with isopropanol and drying the transparent conductive substrate by nitrogen and then annealing at 70° C. for 30 min.
